(19) United States
(12) Patent Application Publication
(10) Pub. No.: US 2025/0318359 A1
(43) Pub. Date: Oct. 9, 2025

(54) METHOD OF MANUFACTURING DISPLAY DEVICE, DISPLAY DEVICE, AND ELECTRONIC DEVICE COMPRISING DISPLAY DEVICE

(71) Applicant: Samsung Display Co., Ltd., Yongin-si (KR)

(72) Inventors: Gi Hyun LEE, Yongin-si (KR); Jin Seok CHOI, Yongin-si (KR); Byeong Guk CHOI, Yongin-si (KR)

(73) Assignee: Samsung Display Co., Ltd., Yongin-si (KR)

(21) Appl. No.: 18/972,043

(22) Filed: Dec. 6, 2024

(30) Foreign Application Priority Data
Apr. 9, 2024 (KR) 10-2024-0047893

(51) Int. Cl. H10K 59/12; H10K 59/80; H10K 71/10

(52) U.S. Cl. CPC H10K 59/1201; H10K 59/876; H10K 71/191

(57) ABSTRACT

A method of manufacturing a display device includes forming a pixel circuit layer including a pixel circuit, and forming a display layer including a light-emitting element disposed on the pixel circuit layer and electrically connected to the pixel circuit. Forming the display layer includes unit process steps. Each of the unit process steps includes obtaining, as part of a first unit process step, cavity effect information about one or more previously formed layers; and forming, as part of a second unit process step, a layer based on the cavity effect information obtained as part of the first unit process step.

### CROSS-REFERENCE TO RELATED APPLICATION(S)

This U.S. non-provisional patent application claims priority to and the benefits of Korean Patent Application No. 10-2024-0047893, under 35 U.S.C. § 119, filed in the Korean Patent Intellectual Property Office on Apr. 9, 2024, the entire contents of which are hereby incorporated by reference.

### BACKGROUND

### 1. Technical Field

The disclosure generally relates to a method of manufacturing a display device, the display device, an electronic device comprising the display device.

### 2. Description of the Related Art

As interest in an information display increases, research and development for display devices are being continuously conducted.

A display device may include sub-pixels respectively including an organic light-emitting diode (OLED). The organic light-emitting diode may be an active light-emitting display element that may have an advantage of not only having a relatively wide viewing angle and relatively excellent contrast, but may also be driven at a relatively low voltage, relatively lightweight, relatively thin, and may have a relatively fast response speed (or time).

An organic light-emitting diode may include a hole transport portion, an electron transport portion, and a light-emitting layer between the hole transport portion and the electron transport portion. Holes provided from the hole transport portion and electrons provided from the electron transport portion may be recombined in the light-emitting layer to generate excitons. The generated excitons may transition from an excited state to a ground state and light may be generated or emitted as part of this transition.

A display device including an organic light-emitting diode may have various optical characteristics including light-emitting efficiency.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

An aspect is directed to providing a method of manufacturing a display device and an electronic device comprising the display device that is capable of improving a light-emitting efficiency of the display device.

An aspect is directed to providing a method of manufacturing a display device and an electronic device comprising the display device that is capable of more precisely forming an intended cavity structure.

An aspect is directed to providing a method of manufacturing a display device and an electronic device comprising the display device that is capable of allowing reliability to be reconsidered during a manufacturing process.

Additional aspects will be set forth in the detailed description, which follows, and in part, will be apparent from the disclosure, or may be learned by practice of the disclosed embodiments and/or the claimed subject matter.

According to an embodiment, a method of manufacturing a display device includes forming a pixel circuit layer including a pixel circuit, and forming a display layer including a light-emitting element disposed on the pixel circuit layer and electrically connected to the pixel circuit. Forming the display layer includes unit process steps. Each of the unit process steps includes obtaining, as part of a first unit process step, cavity effect information about one or more previously formed layers, and forming, as part of a second unit process step, a layer based on the cavity effect information obtained as part of the first unit process step.

In an embodiment, the layer may be formed based on updated target information that is updated based on the cavity effect information obtained as part of the first unit process step.

In an embodiment, the second unit process step may compensate for a process deviation in at least one of the previously formed layers.

In an embodiment, the cavity effect information may include thickness information about one or more of the previously formed layers.

In an embodiment, in response to the previously formed layers being formed thicker or thinner than a target formation range, the layer may be formed thinner or thicker than a target thickness range for the layer.

In an embodiment, the cavity effect information may include surface uniformity information about one or more of the previously formed layers.

In an embodiment, in response to at least one of the previously formed layers being formed with a non-uniform cross-section, the layer may be formed to have a cross-section corresponding to the non-uniform cross-section.

In an embodiment, forming the display layer may include forming an anode electrode. The anode electrode may be at least one of the previously formed layers.

In an embodiment, forming the display layer may include, as steps respectively corresponding to the unit process steps, forming a hole transport portion on the anode electrode, forming a light-emitting layer on the hole transport portion, and forming an electron transport portion on the light-emitting layer.

In an embodiment, forming the hole transport portion may include obtaining, as part of another first unit process step, first cavity effect information about one or more of the previously formed layers, and forming, as part of another second unit process step, the hole transport portion based on the first cavity effect information. The previously formed layers may include the anode electrode.

In an embodiment, forming the display layer may include forming a cathode electrode on the electron transport portion. A portion of the cathode electrode facing the light-emitting layer may be formed to cavity-amplify incident light from the light-emitting layer.

In an embodiment, forming the display layer may include forming a reflective layer on the pixel circuit layer. A portion of the reflective layer facing the light-emitting layer may be formed to cavity-amplify incident light from the light-emitting layer.

In an embodiment, forming the display layer may include, as steps respectively corresponding to the unit process steps, forming a first light-emitting unit, forming a charge generation layer on the first light-emitting unit, and forming a second light-emitting unit on the charge generation layer.

In an embodiment, at least some of the unit process steps may be performed as part of an in-line process in which processes of the in-line process are sequentially performed along a same manufacturing line.

In an embodiment, the display device may be an organic light-emitting diode (OLED) on silicon (OLEDoS) display device.

In an embodiment, a display device may be manufactured according to the manufacturing method.

In an embodiment, the method may further include determining that the process deviation occurred in the at least one of the previously formed layers using the cavity effect information.

According to an embodiment, an electronic device includes a processor configured to provide input image data, a display device configured to display an image based on the input image data and including sub-pixel areas, and a power supply configured to supply power to the display device. The display device being manufactured according to a method including forming a pixel circuit layer including a pixel circuit and forming a display layer including a light-emitting element disposed on the pixel circuit layer and electrically connected to the pixel circuit. Forming the display layer includes unit process steps. Each of the unit process steps includes obtaining, as part of a first unit process step, cavity effect information about one or more previously formed layers, and forming, as part of a second unit process step, a layer based on the cavity effect information obtained as part of the first unit process step.

According to some embodiments, it is possible to provide a method of manufacturing a display device and an electronic device comprising the display device that is capable of improving a light-emitting efficiency of the display device.

According to some embodiments, it is possible to provide a method of manufacturing a display device and an electronic device comprising the display device that is capable of more precisely forming an intended cavity structure.

According to some embodiments, it is possible to provide a method of manufacturing a display device and an electronic device comprising the display device that is capable of allowing reliability to be reconsidered during a manufacturing process.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 illustrates a schematic top plan view of a display device according to an embodiment.

FIG. 2 illustrates a schematic cross-sectional view of a display device according to an embodiment.

FIG. 3 illustrates a schematic cross-sectional view of a display device according to an embodiment.

FIG. 4 and FIG. 5 illustrate schematic cross-sectional views of an anode electrode, a light-emitting structure, and a cathode electrode according to some embodiments.

FIG. 6 illustrates a flowchart of a method of manufacturing a display device according to an embodiment.

FIG. 7 to FIG. 9 illustrate schematic cross-sectional views of unit process steps according to an embodiment.

FIG. 10 to FIG. 18 illustrate schematic views of a manufacturing method of a display device according to an embodiment.

FIG. 19 and FIG. 20 illustrate schematic views of a manufacturing method of a display device according to an embodiment.

FIG. 21 is a schematic block diagram illustrating an electronic device including a display device in accordance with an embodiment.

FIG. 22 is a schematic diagram illustrating an example where the electronic device of FIG. 21 is implemented as a smartphone.

FIG. 23 is a schematic diagram illustrating an example where the electronic device of FIG. 21 is implemented as a tablet computer.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid Further, various embodiments may be unnecessarily obscuring various embodiments. different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items-it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4. Furthermore, the expression “being the same” may mean “being substantially the same.” For instance, the expression “being the same” may include a range that can be tolerated by those skilled in the art. Other expressions may also be expressions from which “substantially” has been omitted.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, a method of manufacturing a display device, the display device, and an electronic device including the display device according to various embodiments will be described with reference to the accompanying drawings.

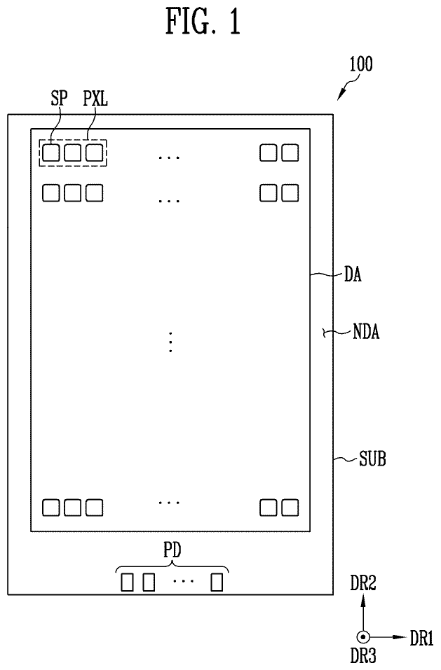

FIG. 1 illustrates a schematic top plan view of a display device according to an embodiment.

Referring to FIG. 1, a display device 100 according to an embodiment may be configured to emit light.

The display device 100 may include a display area DA and a non-display area NDA. The display device 100 may be configured to display an image through the display area DA. The non-display area NDA may be disposed outside the display area DA. For instance, the non-display area NDA may be disposed around the display area DA in a view in the third direction DR3.

The display device 100 may include a substrate SUB, sub-pixels SP, and pads PD.

The display device 100 may be applied to (or used in) various fields. For example, the display device 100 may be a device for displaying a moving image or a still image, and may be used as a display screen of a portable electronic device, such as a mobile phone, a smart phone, a tablet personal computer (PC), a smart watch, a watch phone, a mobile communication terminal, an electronic note, an electronic book, a portable multimedia player (PMP), a navigation device, an ultra-mobile PC (UMPC), etc., and may be used as a display screen of various other products, such as a television set, a laptop computer, a monitor, a billboard, an Internet of things (IOT) device, a consumer appliance, etc.

In some embodiments, in a case that the display device 100 is used as a display screen for a head mounted display (HMD), a virtual reality (VR) device, a mixed reality (MR) device, or an augmented reality (AR) device, the display device 100 may be positioned relatively close to a user's eyes. The sub-pixels SP with relatively high integration (or relatively large number of sub-pixels per inch) may be used to increase a display quality. To increase the integration of the sub-pixels SP, the substrate SUB may be provided as a silicon substrate. The sub-pixels SP may be formed on and/or in the substrate SUB, which may be a silicon substrate. The display device 100 including multiple layers formed on the substrate SUB, which may be a silicon substrate, may be referred to as an organic light emitting diode (OLED) on silicon (OLEDoS) display device.

The sub-pixels SP may be disposed in the display area DA on the substrate SUB. The sub-pixels SP may be arranged in a matrix formation along a first direction DR1 and a second direction DR2 transverse to the first direction DR1. However, embodiments are not limited to the aforementioned sub-pixel arrangement. F For example, the sub-pixels SP may be arranged in a zigzag formation along the first direction DR1 and the second direction DR2. For example, the sub-pixels SP may be disposed according to a Pentile™ arrangement. The first direction DR1 may be a row direction, and the second direction DR2 may be a column direction.

A plane may be defined by the first direction DR1 and the second direction DR2, and may be defined based on a plane on which the substrate SUB may be disposed. In some embodiments, a third direction DR3 may be a thickness direction of the substrate SUB, and the third direction DR3 may be a light-emitting direction of the display device 100. As used herein, the phrase “in a plan view” refers (unless stated otherwise) to a view of an element, such as display device 100, in the third direction DR3.

The sub-pixels SP may have various shapes in a plan view, and the shapes of the sub-pixels SP are not limited to any specific example. For instance, any one or more suitable geometric figures may define the shapes of the sub-pixels SP in a plan view.

Each of the sub-pixels SP may include at least one light-emitting element configured to generate light. The sub-pixels SP may respectively generate light of a specific (or selected) color, such as red, green, blue, cyan, magenta, yellow, and/or the like. Among the sub-pixels SP, two or more sub-pixels SP may configure a pixel PXL. For example, as shown in FIG. 1, three sub-pixels SP may configure a pixel PXL.

Hereinafter, the sub-pixels SP include a first sub-pixel SP1 that provides light of a first color (for example, a red color), a second sub-pixel SP2 that provides light of a second color (for example, a green color), and a third sub-pixel SP3 that provides light of a third color (for example, a blue color).

In some embodiments, the first sub-pixel SP1 is a red pixel and may provide light in a wavelength band of about 600 nm to about 750 nm. The second sub-pixel SP2 is a green pixel and may provide light in a wavelength band of about 480 nm to about 560 nm. The third sub-pixel SP3 is a blue pixel and may provide light in a wavelength band of about 370 nm to about 460 nm.

A constituent element to control the sub-pixels SP may be disposed in the non-display area NDA on the substrate SUB. For example, wires electrically connected to the sub-pixels SP (for example, gate lines and data lines for driving the sub-pixels SP) may be disposed in the non-display area NDA and may extend into the display area DA. A gate driver, a data driver, a voltage generator, a controller, and/or a temperature sensor for obtaining (or generating) driving signals supplied to the sub-pixels SP may be integrated in (or as part of) the non-display area NDA of the display device 100. However, embodiments are not limited to the aforementioned examples.

The pads PD are disposed in the non-display area NDA on the substrate SUB. The pads PD may be electrically connected to the sub-pixels SP through, for instance, wires (or lines). For example, the pads PD may be electrically connected to the sub-pixels SP through data lines. The pads PD may provide an interface between constituent elements in the display area DA and/or the non-display area NDA and other constituent elements of the display device 100. In embodiments, voltages and signals for operations of one or more constituent elements included in (or as part of) the display device 100 may be provided from a driver integrated circuit through at least one of the pads PD.

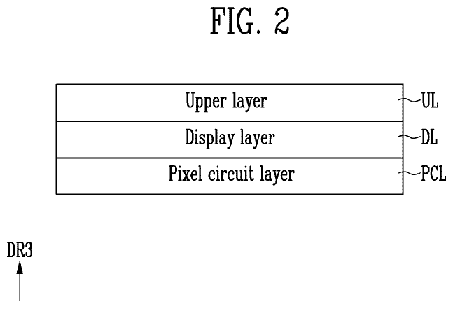

A cross-sectional structure and the like of the display device 100 according to an embodiment will be described with reference to FIG. 2 to FIG. 5.

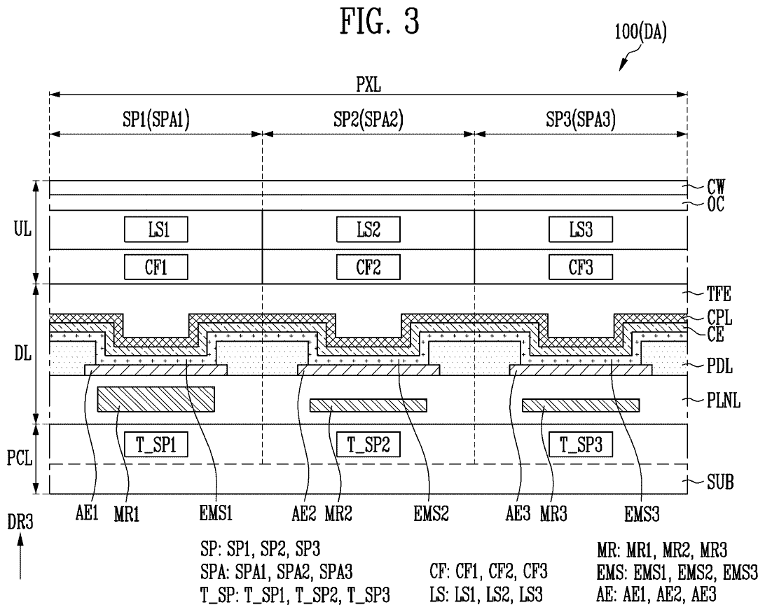

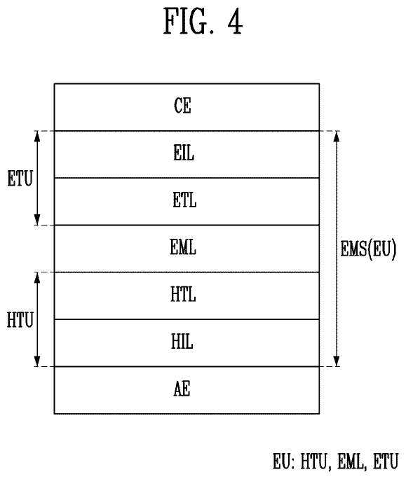

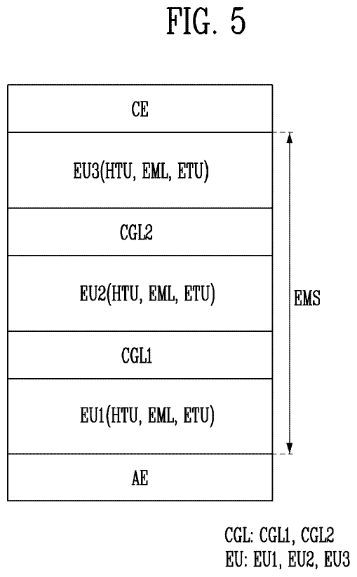

FIG. 2 illustrates a schematic cross-sectional view of a display device according to an embodiment. FIG. 3 illustrates a schematic cross-sectional view of a display device according to an embodiment. In some embodiments, FIG. 3 schematically illustrates a cross-sectional structure of the display device 100 in the display area DA. FIG. 4 and FIG. 5 illustrate schematic cross-sectional views of an anode electrode, a light-emitting structure, and a cathode electrode according to an embodiment.

Referring to FIG. 2 to FIG. 5, the display device 100 may include a pixel circuit layer PCL, a display layer DL, and an upper layer UL.

According to an embodiment, a pixel PXL may be formed in the display area DA, and the sub-pixels SP may include the first sub-pixel SP1 that provides light of a red color, the second sub-pixel SP2 that provides light of a green color, and the third sub-pixel SP3 that provides light of a blue color. The sub-pixels SP may form a sub-pixel area SPA in which light of a color is provided. The sub-pixel area SPA may include a first sub-pixel area SPA1 in which red color light is provided, a second sub-pixel area SPA2 in which green color light is provided, and a third sub-pixel area SPA3 in which blue color light is provided.

In some embodiments, the pixel circuit layer PCL may include a substrate SUB and a circuit element. In some embodiments, the circuit element may include one or more transistors T_SP and one or more capacitors.

The substrate SUB may include a silicon wafer substrate formed using a semiconductor process. The substrate SUB may include a semiconductor material suitable for forming circuit elements. For example, the semiconductor material may include silicon, germanium, and/or silicon-germanium, but embodiments are not limited to the aforementioned materials. The substrate SUB may be provided from a bulk wafer, an epitaxial wafer, an epitaxial layer, a silicon on insulator (SOI) layer, or a semiconductor on insulator (SeOI) layer, but embodiments are not limited to the aforementioned examples. In some embodiments, the substrate SUB may include a glass substrate. In some embodiments, the substrate SUB may include a polyimide (PI) substrate.

The circuit element may be formed on the substrate SUB. In some embodiments, the transistor T_SP may include a first transistor T_SP1 configured to drive a light-emitting element of the first sub-pixel SP1, a second transistor T_SP2 configured to drive a light-emitting element of the second sub-pixel SP2, and a third transistor T_SP3 configured to drive a light-emitting element of the third sub-pixel SP3.

The display layer DL may be disposed (or otherwise formed) on the pixel circuit layer PCL. In some embodiments, the display layer DL may be manufactured by sequentially patterning multiple layers on the pixel circuit layer PCL.

The display layer DL may include a light-emitting element, and may include a cavity structure for light that is provided by the light-emitting element. According to some embodiments, the cavity structure may be formed to improve light emission efficiency for light that is provided by the light-emitting element.

The cavity structure may implement a cavity or microcavity effect, such as an optical cavity or microcavity effect. Hereinafter, a cavity or microcavity effect will be referred to as a cavity effect. For example, light emitted by a light-emitting structure EMS may be amplified by a cavity effect between a reflective layer MR and a cathode electrode CE, thereby improving light emission efficiency.

In each of the first to third sub-pixels SP1 to SP3, each of first to third light-emitting structures EMS1 to EMS3 may emit light with a determined (or selected) wavelength (or range of wavelengths). At least one cavity (or resonance) distance suitable to provide a cavity effect in association with each of the first to third sub-pixels SP1 to SP3 may be defined for the light-emitting elements of the first to third sub-pixels SP1 to SP3. According to an embodiment, each of layers disposed between the reflective layer MR and the cathode electrode CE (or layers disposed between the anode electrode AE and the cathode electrode CE) may have a thickness according to a determined (or selected) standard, and may have a substantially flat surface. For example, based on the determined cavity distance, each of the layers disposed between the reflective layer MR and the cathode electrode CE may be formed having a determined thickness range.

In some embodiments, light may be amplified in a cavity or cavity path of light. In some embodiments, the cavity path of light may be defined below the cathode electrode CE. In some embodiments, the cavity path of light may be defined between the reflective layer MR and the cathode electrode CE. In some embodiments, the cavity path of light may be defined between the reflective layer MR and the capping layer CPL. In some embodiments, the cavity path of light may be defined between the anode electrode AE and the cathode electrode CE. In some embodiments, the cavity path of light may be defined between the anode electrode AE and the capping layer CPL.

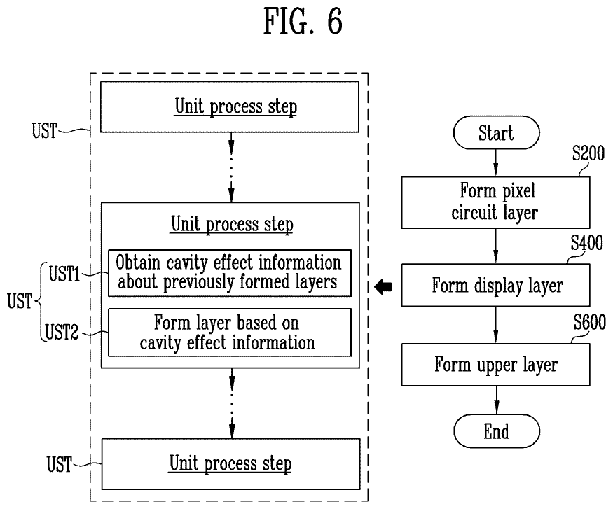

According to an embodiment, in a case that the display layer DL is manufactured, a factor that may affect resonance in a cavity, such as the thickness and/or shape of one or more layers forming the cavity, may be determined based on the thickness and/or shape of one or more layers formed before a layer of the cavity is to be formed. The factor(s) (e.g., layer thickness, layer shape, etc.) may be referred to as cavity information. In the first to third sub-pixels SP1 to SP3, the cavity structure may be defined, and the cavity effect may be provided, thereby improving the light emission efficiency of the display device 100. This will be described in more detail later with reference to the drawings after FIG. 6.

The display layer DL may form a light-emitting element, such as an organic light-emitting diode. The display layer DL may include a reflective layer MR, a planarization layer PLNL, an anode electrode AE, a pixel defining layer PDL, a light-emitting structure EMS, a cathode electrode CE, a capping layer CPL, and an encapsulation layer TFE.

The reflective layer MR may be disposed on the pixel circuit layer PCL, and may be covered (or overlapped) by the planarization layer PLNL in a plan view. The reflective layer MR may be disposed in the sub-pixel area SPA in a plan view.

The reflective layer MR may form a reflective member (e.g., a lower reflective member) for forming a cavity structure in each of the sub-pixels SP. Some of the light emitted from the light-emitting structure EMS may be reflected by the reflective layer MR and directed in the display direction (for example, in the third direction DR3) of the display device 100.

In some embodiments, the reflective layer MR may include a reflective structure layer including a reflective material and a step forming layer for adjusting a height of a reflective surface formed by the reflective layer MR. Each of the reflective structure layer and the step forming layer may include a single layer or multiple layers. The reflective structure layer may include at least one of aluminum (Al) and titanium (Ti). The step forming layer may include tetraethyl orthosilicate (TEOS). However, embodiments are not limited to the above-noted examples or materials.

In some embodiments, the reflective layer MR may include a first reflective layer MR1 disposed in the first sub-pixel area SPA1, a second reflective layer MR2 disposed in the second sub-pixel area SPA2, and a third reflective layer MR3 disposed in the third sub-pixel area SPA3. In some embodiments, each of the first to third reflective layers MR1 to MR3 may have a different reflective surface (e.g., upper surface) (or a difference in distance of the reflective surface from the substrate SUB) based on the cavity distance of light provided by a corresponding one of the first to third sub-pixels SP1 to SP3. Corresponding reflective surfaces of the first to third reflective layers MR1 to MR2 may respectively face a corresponding one of the first to third light-emitting structures EMS1 to EMS3 of the respective first to third sub-pixels SP1 to SP3 in the third direction DR3. Hereinafter, a reflective surface will be referred to as a reflective upper surface or an upper surface of a corresponding reflective layer. For example, the upper surface of the first reflective layer MR1 may be formed substantially higher in the third direction DR3 than the upper surfaces of the second and third reflective layers MR2 and MR3 relative to, for example, the substrate SUB.

The planarization layer PLNL may be disposed below the light-emitting element, and may be disposed on the reflective layer MR. For instance, the planarization layer PLNL may be disposed between the anode electrode AE and the substrate SUB. The planarization layer PLNL may offset (or compensate for) a step difference caused by other layers formed below a surface (e.g., upper surface) of the planarization layer PLNL on which a light-emitting element may be formed. The planarization layer PLNL may include an organic material. For example, the planarization layer PLNL may include tetraethyl orthosilicate (TEOS). However, embodiments are not limited to any specific material for and/or configuration of the planarization layer PLNL.

The anode electrode AE may be disposed on the planarization layer PLNL. The anode electrode AE may be electrically connected to circuit elements of the pixel circuit layer PCL through a contact portion penetrating (or formed in) the planarization layer PLNL and/or the like.

The anode electrode AE may include a first anode electrode AE1 included in the first sub-pixel SP1 and that may be electrically connected to a portion of the light-emitting structure EMS disposed in the first sub-pixel area SPA1, a second anode electrode AE2 included in the second sub-pixel SP2 and that may be electrically connected to a portion of the light-emitting structure EMS disposed in the second sub-pixel area SPA2, and a third anode electrode AE3 included in the third sub-pixel SP3 and that may be electrically connected to a portion of the light-emitting structure EMS disposed in the third sub-pixel area SPA3. The anode electrode AE may be electrically connected to the transistor T_SP, and may supply an anode signal (for example, a voltage) for the light-emitting structure EMS to emit light.

The anode electrode AE may include various conductive materials. For example, the anode electrode AE may include a transparent conductive material including an oxide. For example, the transparent conductive material may include at least one of indium tin oxide (ITO), indium zinc oxide (IZO), indium gallium zinc oxide (IGZO), antimony zinc oxide (AZO), indium tin zinc oxide (ITZO), zinc oxide (ZnO), and tin oxide (SnO₂). In some embodiments, the anode electrode AE may be an electrode layer including ITO. However, embodiments are not limited to the above-noted materials.

According to an embodiment, some of the light emitted by the light-emitting structure EMS may be transmitted through the anode electrode AE and may be applied to (or incident on) the reflective layer MR, and the applied light may be reflected by (or off) the reflective layer MR and transmitted through the anode electrode AE and emitted to the outside of the display device 100 (for example, emitted from the display device 100 along the third direction DR3). The optical cavity structure may be defined in each sub-pixel SP.

The light-emitting structure EMS may be disposed on the anode electrode AE in the sub-pixel area SPA, and may be electrically connected to the anode electrode AE. A portion of the light-emitting structure EMS may be disposed on the pixel defining layer PDL.

The light-emitting structure EMS may include a multi-layered structure electrically connected between the anode electrode AE and the cathode electrode CE.

The light-emitting structure EMS may include a light-emitting unit (or unit light-emitting structure) EU including multiple layers.

The light-emitting unit EU may include multiple light-emitting structures including a hole transport portion HTU, a light-emitting layer (or light generating layer) EML, and an electron transport portion ETU. One or more respective layers forming the light-emitting structure EMS may include an organic material, and in some embodiments, one or more of the respective layers forming the light-emitting structure EMS may further include an inorganic material, such as a metal-containing compound, a quantum dot, a semiconductor crystal, and/or a semiconductor cluster.

The hole transport portion HTU may include a multi-layered structure having multiple layers each containing different materials from one another. For example, the hole transport portion HTU may include a hole injection layer HIL and a hole transport layer HTL, and in some embodiments, the hole transport portion HTU may further include at least one of a light-emitting auxiliary layer and an electron blocking layer.

The light-emitting layer EML may include a material configured to emit light of a color. The light-emitting layer EML may include a host and a dopant. The host of the light-emitting layer EML may be a light-emitting material that may capture carriers (electrons and holes) for light generation, and may induce excitons to be generated and emitted. The dopant may include, for instance, at least one of a phosphorescent dopant and a fluorescent dopant. In some embodiments, examples of the dopant are not limited to the aforementioned types of dopants. In some embodiments, the dopant may include at least one of an organic material and a metal complex.

The electron transport portion ETU may include a multi-layered structure having multiple layers each containing different materials from one another. The electron transport portion ETU may include an electron injection layer EIL and an electron transport layer ETL, and in some embodiments, the electron transport portion ETU may further include at least one of an electron buffer layer and a hole blocking layer.

According to an embodiment (such as illustrated in FIG. 4), the light-emitting structure EMS may include a single light-emitting unit EU. The light-emitting structure EMS may include different materials in respective sub-pixels SP. For example, the light-emitting structure EMS may include a first light-emitting structure EMS1 disposed in the first sub-pixel area SPA1 and including a material for emitting light of a first color, a second light-emitting structure EMS2 disposed in the second sub-pixel area SPA2 and including a material for emitting light of a second color, and a third light-emitting structure EMS3 disposed in the third sub-pixel area SPA3 and including a material for emitting light of a third color.

According to an embodiment (such as depicted in FIG. 5), the light-emitting structure EMS may have a tandem structure. For example, the light-emitting structure EMS may include multiple light-emitting units EU stacked on one another and a charge generation layer CGL disposed between adjacent light-emitting units EU among the multiple light-emitting units EU. The charge generation layer CGL may be disposed between the light-emitting units EU to guide a current flow. In embodiments, the charge generation layer CGL may have a stacked structure of a p-dopant layer and an n-dopant layer. The light-emitting structure EMS may be disposed across the first to third sub-pixel areas SPA1 to SPA3, and a separator structure may be formed on the pixel defining layer PDL or in the pixel defining layer PDL so that at least a portion of the light-emitting structure EMS is disconnected from at least another portion of the light-emitting structure EMS. The separator structure may be a trench structure, and in some embodiments, the separator structure may include a T-shaped protrusion (for example, a tip structure) in a view in a direction perpendicular to the third direction DR3.

In some embodiments, the light-emitting units EU may include a first light-emitting unit EU1, a second light-emitting unit EU2, and a third light-emitting unit EU3, and the charge generation layer CGL may include a first charge generation layer CGL1 and a second charge generation layer CGL2. In some embodiments, in the light-emitting structure EMS, the first light-emitting unit EU1, the first charge generation layer CGL1, the second light-emitting unit EU2, the second charge generation layer CGL2, and the third light-emitting unit EU3 may be sequentially disposed in the recited order.

The pixel defining layer PDL may be disposed on the anode electrode AE. The pixel defining layer PDL may include an opening exposing the anode electrode AE. In embodiments, the pixel defining layer PDL may include an inorganic material. The pixel defining layer PDL may include multiple stacked inorganic layers. For example, the pixel defining layer PDL may include at least one of a silicon oxide (SiOx) and a silicon nitride (SiNx). In some embodiments, the pixel defining layer PDL may include an organic material or may include both an organic material and an inorganic material. However, the material of the pixel defining layer PDL is not limited to the above-noted examples.

The cathode electrode CE may be disposed on the light-emitting structure EMS. The cathode electrode CE may extend across the first to third sub-pixels SP1 to SP3. The cathode electrode CE may be provided as a common electrode for the first to third sub-pixels SP1 to SP3.

The cathode electrode CE may be a thin metal layer with a thickness sufficient to transmit light emitted from the light-emitting structure EMS and/or reflected from the reflective layer MR. The cathode electrode CE may be made of (or include) at least one of a metallic material and a transparent conductive material and may have a relatively thin thickness. In embodiments, the cathode electrode CE may include at least one of various transparent conductive materials, including, for instance, at least one of indium tin oxide (ITO), indium zinc oxide (IZO), indium gallium zinc oxide (IGZO), antimony zinc oxide (AZO), indium tin zinc oxide (ITZO), zinc oxide (ZnO), and tin oxide (SnO₂). In some embodiments, the cathode electrode CE may include at least one of silver (Ag), magnesium (Mg), and a mixture of silver (Ag) and magnesium (MG). However, the material of the cathode electrode CE is not limited to the aforementioned examples.

One of the anode electrodes AE, a portion of the light-emitting structure EMS overlapping the one of the anode electrodes AE, and a portion of the cathode electrode CE overlapping the one of the anode electrodes AE may be understood as forming a light-emitting element in a corresponding one of the sub-pixels SP.

The capping layer CPL may be disposed on the cathode electrode CE, and may passivate other layers disposed below the capping layer CPL. The capping layer CPL may include an inorganic material.

The encapsulation layer TFE may be disposed on the capping layer CPL. The encapsulation layer TFE may passivate other layers disposed below the encapsulation layer TFE. In embodiments, the encapsulation layer TFE may include a structure in which one or more inorganic films and one or more organic films are alternately stacked with each other. For example, the inorganic film may include at least one of a silicon nitride, a silicon oxide, and a silicon oxynitride (SiOxNy). For example, the organic film may include an organic insulating material, such as at least one of an acrylic resin, an epoxy resin, a phenol resin, a polyamide resin, a polyimide resin, an unsaturated polyester resin, a polyphenylene ether resin, a polyphenylene sulfide resin, and a benzocyclobutene. However, the materials of the organic film and the inorganic film of the encapsulation layer TFE are not limited to the above-noted examples.

Color filters CF may be disposed on the encapsulation layer TFE. The color filters CF may transmit light of a color. For example, the color filters CF may include at least one of a dye and pigment that selectively transmit light of a color. The color filters CF may include a first color filter CF1 included in the first sub-pixel SP1 and passing light of a red color corresponding to the first sub-pixel SP1, a second color filter CF2 included in the second sub-pixel SP2 and passing light of a green color corresponding to the second sub-pixel SP2, and a third color filter CF3 included in the third sub-pixel SP3 and passes light of a blue color corresponding to the third sub-pixel SP3.

Lenses LS may be disposed on the color filters CF. The lenses LS may include a first lens LS1 disposed in the first sub-pixel area SPA1 and included in the first sub-pixel SP1, a second lens LS2 disposed in the second sub-pixel area SPA2 and included in the second sub-pixel SP2, and a third lens LS3 disposed in the third sub-pixel area SPA3 and included in the third sub-pixel SP3.

The lenses LS may have a relatively high refractive index, may output light provided from the display layer DL to an intended (or directed) path, and may improve the light emission efficiency of the display device 100. In some embodiments, the lenses LS may be omitted.

An overcoat layer OC may be disposed on the lenses LS. The overcoat layer OC may cover other layers disposed below the overcoat layer OC, and may include various materials suitable for protecting other layers from foreign substances, such as dust, moisture, and/or the like. For example, the overcoat layer OC may include at least one of an inorganic insulating film and an organic insulating film. For example, the overcoat layer OC may include an epoxy resin, but embodiments are not limited to this example.

A cover window CW may be disposed on the overcoat layer OC. The cover window CW may protect other layers disposed below the cover window CW. The cover window CW may include a glass material. However, embodiments are not limited to the aforementioned example. In some embodiments, the cover window CW may be an encapsulation glass, and in some embodiments, the cover window CW may be omitted.

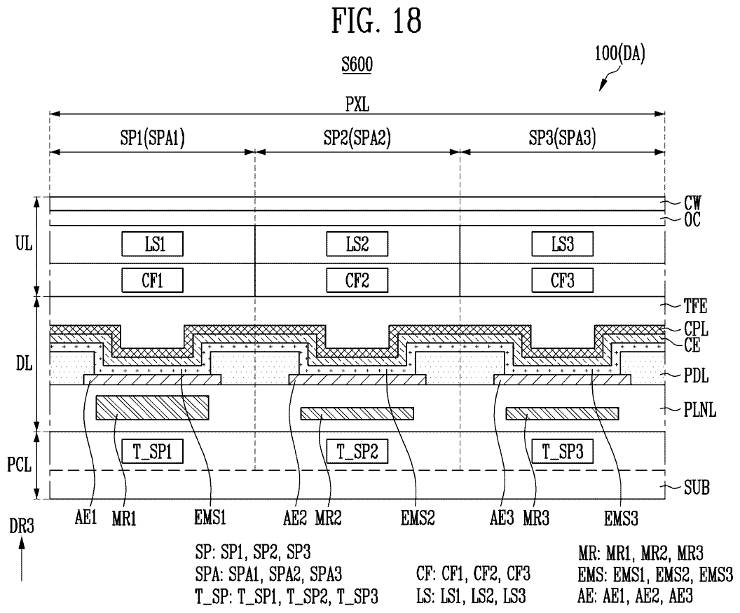

Hereinafter, a method of manufacturing the display device 100 according to some embodiments will be described with reference to FIG. 6 to FIG. 20. Descriptions that may be redundant to those described above are simplified or are not repeated.

A method of manufacturing the display device 100 including multiple unit process steps UST will be described with reference to FIG. 6 to FIG. 9.

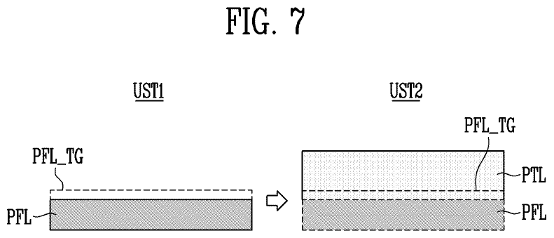

FIG. 6 illustrates a flowchart of a method of manufacturing a display device according to an embodiment. FIG. 6 further illustrates the unit process steps UST included in step S400 of forming the display layer DL. FIG. 7 to FIG. 9 illustrate schematic cross-sectional views of the unit process steps UST according to an embodiment.

Referring to FIG. 6, the method of manufacturing the display device 100 according to an embodiment may include forming a pixel circuit layer PCL (S200), forming a display layer DL (S400), and forming an upper layer (S600).

In some embodiments, forming the display layer DL (S400) may include multiple unit process steps UST.

Each of the unit process steps UST may be at least some of the process steps performed in forming the display layer DL (S400). For example, forming the display layer DL (S400) may include multiple process steps performed as a unit process step UST, and in some embodiments, forming the display layer DL (S400) may further include one or more process steps that are not performed as part of a unit process step UST. However, embodiments are not limited to the aforementioned examples, and in some embodiments, respective process steps of forming the display layer DL (S400) may all be configured as a unit process step UST.

A unit process step UST may be a process step of forming a layer forming a portion of the display layer DL, and may include a first unit process step UST1 and a second unit process step UST2 performed after the first unit process step UST1.

The first unit process step UST1 may include obtaining cavity effect information about one or more previously formed layers PFL.

In or as part of the first unit process step UST1, the previously formed layer(s) PFL may be or include a layer formed before a layer PTL that is to be formed in the corresponding unit process step UST.

For example, in a case that the layer PTL to be formed as part of a unit process step UST is the hole injection layer HIL, the previously formed layers PFL may be layers formed below the hole injection layer HIL and may include, for instance, an anode electrode AE and a reflective layer MR. In a case that the layer PTL to be formed in a unit process step UST is the hole transport layer HTL, the previously formed layers PFL may be layers formed below the hole transport layer HTL and may include, for example, an anode electrode AE, a reflective layer MR, a hole injection layer HIL, and the like. In a case that the layer PTL to be formed in a unit process step UST is the light-emitting layer EML, the previously formed layers PFL may be layers formed below the light-emitting layer EML and may include, for example, an anode electrode AE, a reflective layer MR, a hole injection layer HIL, a hole transport layer HTL, and the like. In a case that the layer to be formed in a unit process step UST is the hole transport layer HTL, the previously formed layers PFL may be layers formed below the hole transport layer HTL and may include, for instance, an anode electrode AE, a reflective layer MR, a hole injection layer HIL, a hole transport layer HTL, a light-emitting layer EML, and the like. In a case that the layer PTL to be formed in a unit process step UST is the hole injection layer HIL, the previously formed layers PFL may be layers formed below the hole injection layer HIL and may include, for instance, an anode electrode AE, a reflective layer MR, a hole injection layer HIL, a hole transport layer HTL, a light-emitting layer EML, a hole transport layer HTL, and the like. Other layers PTL and previously formed layers PFL may be defined similarly to those described above.

As part of the first unit process step UST1, cavity effect information about the layer(s) formed in a previous unit process step UST (for example, the previously formed layers PFL) may be obtained.

In some embodiments, the cavity effect information is information obtained as part of the first unit process step UST1, and may be information for changing the cavity structure defined in the sub-pixels SP (or the display layer DL). The cavity effect information is information that may be determined about the previously formed layers PFL as part of the first unit process step UST1, and may be information on a factor affecting the cavity structure.

For example, the factor affecting the cavity structure may be thickness information of one or more of the previously formed layer(s) PFL. A step of measuring the thickness of the previously formed layer(s) PFL may be performed as part of the first unit process step UST1.

In some implementations, the factor affecting the cavity structure may be surface uniformity information about one or more of the previously formed layers PFL. As part of the first unit process step UST1, a step of obtaining a cross-sectional image of the previously formed layer(s) PFL may be performed. As part of the first unit process step UST1, a step of obtaining numerical information, such as a surface slope, of the previously formed layer(s) PFL may be performed.

However, embodiments are not limited to the above-noted examples of factors affecting the cavity structure. In some embodiments, the factor affecting the cavity structure may be various physical factors that may be determined about the previously formed layers PFL. It is also contemplated that the factors affecting the cavity structure may be relative to a single previously formed layer PFL or may be relative to two or more previously formed layers PFL. For example, surface slopes may be determined relative to a first layer or a second layer on the first layer, or may be determined in the aggregate, e.g., relative to the combination of the first layer and the second layer.

The second unit process step UST2 may include forming a layer based on the cavity effect information. The second unit process step UST2 may be a process step in which factors that may affect the cavity structure are compensated. For instance, the layer PTL to be formed in a case that the display layer DL is being formed may be formed based on updated information (or build specifications) that is updated based on the cavity effect information so that conditions associated with the cavity effect information about the previously formed layer(s) PFL may be compensated. For example, the second unit process step UST2 may be a step of compensating for a process deviation determined using the cavity effect information obtained as part of the first unit process step UST1. In a case that the display layer DL being formed, an intended cavity structure may be more precisely formed, and a relatively high light emission efficiency may be determined or obtained based on the intended structure.

As part of the second unit process step UST2, the layer PTL formed based on the cavity effect information may be a layer PTL to be formed in the corresponding unit process step UST.

As part of the second unit process step UST2, the cavity effect information obtained as part of the first unit process step UST1 may be reflected to form a layer PTL based on updated information (for example, as updated cavity effect information, a target thickness, a target surface uniformity, and/or the like of the layer PTL to be formed).

For example, in a case that the factor affecting the cavity structure is information about the thickness of the previously formed layer(s) PFL, the layer PTL to be formed may be formed thinner than as originally intended in a case in which the previously formed layer(s) PFL was formed thicker than intended, and the layer PTL to be formed may be formed thicker than as originally intended in a case in which the previously formed layer(s) PFL was formed thinner than intended.

In some embodiments, in a case that the factor affecting the cavity structure is surface uniformity information, the layer PTL to be formed may be formed to have a shape complementary to the surface formed by the previously formed layer(s) PFL. Forming complementary shapes may allow a more planar surface to be obtained once the layer PTL is formed on the previously formed layer(s) PFL.

In some embodiments, the layer PTL may be formed according to the updated cavity effect information based on the cavity effect information about the previously formed layers PFL so that the cavity structure may be more precisely designed (or formed) in the display layer DL, and as intended, light may be appropriately cavity-amplified to improve light emission efficiency of the display device 100 versus a case in which cavity formation deviates from an intended specification.

In a case of forming a determined layer (e.g., the layer PTL that is to be formed), as the cavity effect information about previously formed layer(s) (e.g., the previously formed layer(s) PFL) is updated, risks (or deviations from intended specifications) that may occur during process procedures may be offset (or mitigated), thereby improving process performance and improving the quality of cavity formation.

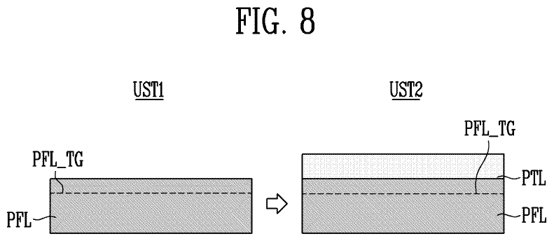

FIGS. 7 and 8 schematically illustrate a process in which thickness information for the layers PTL formed in the second unit process steps UST2 is compensated based on the thickness information about the previously formed layer(s) PFL affecting the cavity structure.

Referring to FIG. 7, as part of the first unit process step UST1, a previously formed layer PFL may be formed thinner than an intended range to be manufactured. For example, in a case of forming the previously formed layer PFL, the previously formed layer PFL may be intended to have a thickness equal to a target formation range PFL_TG, but the previously formed layer PFL may be manufactured to have a thickness that is thinner than the target formation range PFL_TG. The difference may be determined as part of obtaining the cavity effect information as part of the first unit process step UST1. As part of the second unit process step UST2, the layer PTL to be formed may be formed thicker than originally intended, e.g., thicker by a difference between the target formation range PFL_TG and the thickness of the previously formed layer PFL, to compensate for the process deviation that occurred during formation of the previously formed layer PFL. Modifying the formation of the layer PTL may allow an aggregate target formation range to be obtained for forming both the previously formed layer PFL and the layer PTL.

Referring to FIG. 8, the previously formed layer PFL may be manufactured thicker than an intended range to be manufactured. For example, in a case of forming the previously formed layer PFL, the previously formed layer PFL may be intended to have a thickness equal to the target formation range PFL_TG, but the previously formed layer PFL may be formed to have a thickness that is thicker than the target formation range PFL_TG. The difference may be determined as part of obtaining the cavity effect information as part of the first unit process step UST1. As part of the second unit process step UST2, the layer PTL to be formed may be formed thinner than originally intended, e.g., thinner by a difference between the target formation range PFL_TG and the thickness of the previously formed layer PFL, to compensate for the process deviation that occurred during formation of the previously formed layer PFL.

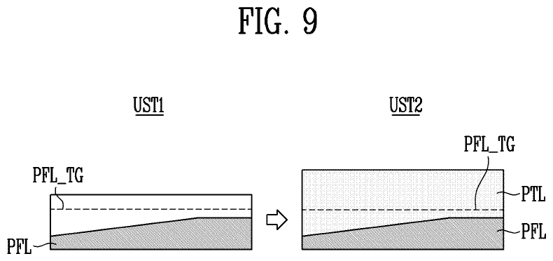

FIG. 9 schematically illustrates a process in which the surface uniformity information about the layers PTL formed in the second unit process step UST2 is compensated based on the surface uniformity information about the previously formed layer(s) PFL affecting the cavity structure. Modifying the formation of the layer PTL may allow an aggregate target formation range to be obtained for forming both the previously formed layer PFL and the layer PTL.

Referring to FIG. 9, the previously formed layer PFL may have a non-uniform cross section (for example, an inclined surface) in at least a portion of the previously formed layer PFL. For example, the previously formed layer PFL may be intended to have a cross-sectional structure corresponding to the target formation range PFL_TG, but the previously formed layer PFL may have a non-uniform cross-section different from the target formation range PFL_TG. The difference may be determined as part of obtaining the cavity effect information as part of the first unit process step UST1. As part of the second unit process step UST2, the layer PTL to be formed may be formed thinner or thicker so that the previously formed layer PFL having the non-uniformly formed portion with respect to the target formation range PFL_TG may be compensated to obtain an aggregate target formation range for forming both the previously formed layer PFL and the layer PTL.

A method of manufacturing the display device 100 according to an embodiment will be described in connection with the unit process steps UST described above with reference to FIG. 6 to FIG. 9. Descriptions that may be redundant to those described above are simplified or are not repeated.

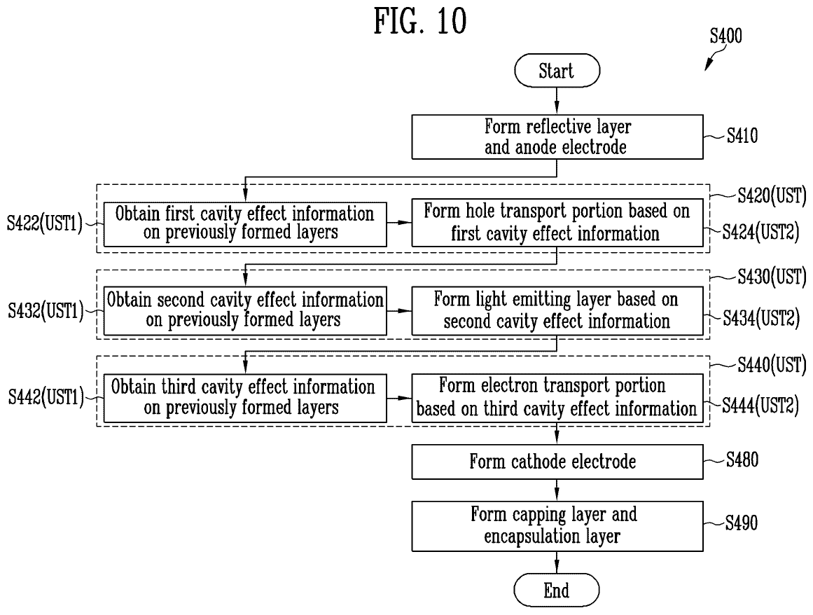

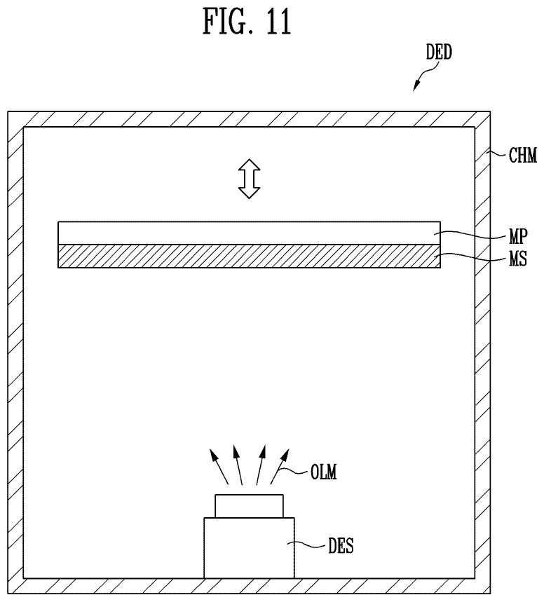

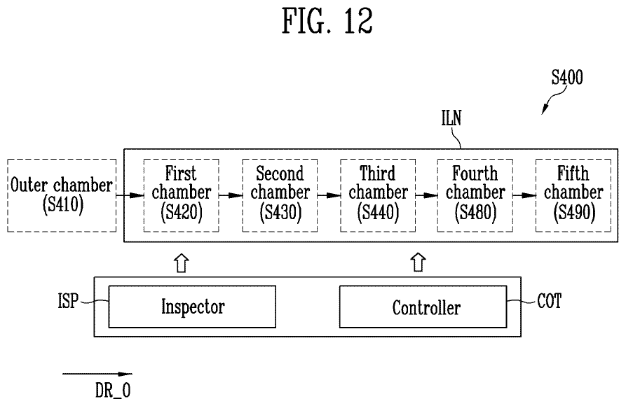

FIG. 10 to FIG. 18 illustrate schematic views of a method of manufacturing a display device according to an embodiment. FIG. 10 illustrates a flowchart of a method for forming a display layer according to an embodiment. FIG. 11 illustrates a schematic cross-sectional view of a deposition device according to an embodiment. FIG. 12 illustrates schematic views of in-line process steps applied to the method for forming the display layer according to an embodiment.

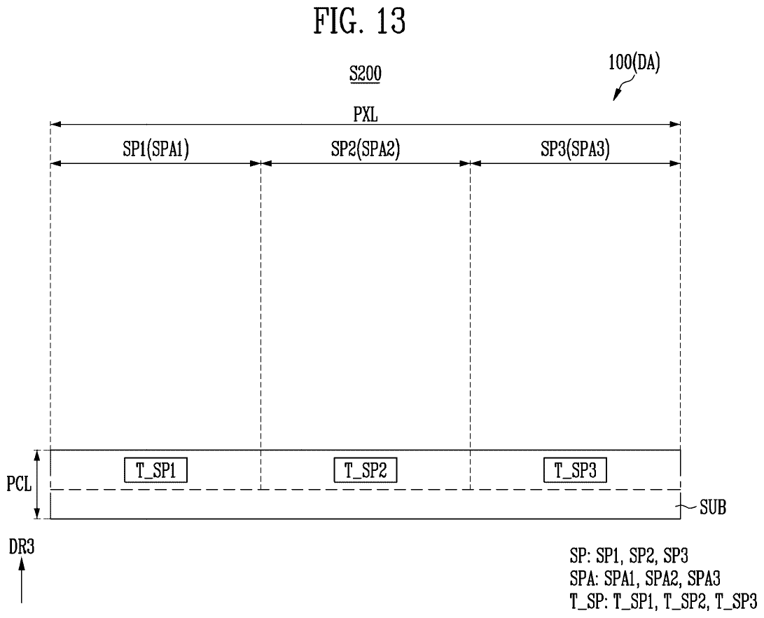

FIG. 13 to FIG. 18 illustrate schematic cross-sectional views of process steps of a method for manufacturing a display device according to an embodiment. For better understanding and ease of description, FIG. 13 to FIG. 18 illustrate schematic cross-sectional structures based on the cross-sectional structure described above with reference to FIG. 3.

Referring to FIG. 10, the forming of the display layer DL (S400) may include forming the reflective layer MR and the anode electrode AE (S410), forming the hole transport portion HTU (S420), forming the light-emitting layer EML (S430), forming the electron transport portion ETU (S440), forming the cathode electrode CE (S480), and forming the capping layer CPL and the encapsulation layer TFE (S490).

Referring to FIG. 6 and FIG. 13, as part of forming the pixel circuit layer PCL (S200), circuit elements for driving the sub-pixels SP may be patterned on the substrate SUB. For example, a first transistor T_SP1 for the first sub-pixel SP1, a second transistor T_SP2 for the second sub-pixel SP2, and a third transistor T_SP3 for the third sub-pixel SP3 may be formed on the substrate SUB.

In some embodiments, a conductive layer and an insulating layer on the substrate SUB may be formed based on a process for manufacturing a semiconductor device. For example, the conductive layer or the insulating layer on the substrate SUB may be formed by a photolithography process, etched by various methods (e.g., wet etching, dry etching, and/or the like), and deposited by various methods (e.g., sputtering, chemical vapor deposition, and/or the like). However, embodiments are not limited to the above-noted examples.

Referring to FIG. 11, a deposition process for forming layers for manufacturing the display device 100 may be performed using a deposition device DED.

The deposition device DED may include a chamber CHM, a deposition source DES, a moving member MP, and a deposition target substrate MS. The deposition target substrate MS may refer to the substrate SUB. The deposition device DED may deposit a deposition material OMM provided from the deposition source DES on the deposition target substrate MS in the chamber CHM. The chamber CHM may accommodate components of the deposition device DED, and the moving member MP may move the deposition target substrate MS.

In some embodiments, referring to FIG. 12, at least some steps of forming the display layer DL (S400) may be performed by an in-line type process ILN. At least some steps of forming the display layer DL (S400) may be sequentially performed in a continuous line forming the in-line type process ILN. In some embodiments, the outer chamber in which the deposition process in step S410 is performed may not be performed as part of the in-line type process ILN. However, embodiments are not limited to the above-noted example.

In some embodiments, first to fifth chambers may be sequentially disposed in the in-line type process ILN, and the deposition process may be sequentially performed along the process direction DR_O. The first chamber may be a chamber CHM for performing step S420. The second chamber may be a chamber CHM for performing step S430. The third chamber may be a chamber CHM for performing step S440. The fourth chamber may be a chamber CHM for performing step S480. The fifth chamber may be a chamber CHM for performing step S490.

In some embodiments, a manufacturing apparatus for manufacturing the display device 100 may include an inspector ISP and a controller COT.

The inspector ISP may be configured to obtain cavity effect information about the previously formed layer(s) PFL as part of the first unit process step UST1. For example, the inspector ISP may be a thickness measuring device, and may be a cross-sectional profile acquisition device. However, embodiments are not limited to these example types of inspectors ISP.

The controller COT may be configured to generally control the manufacturing apparatus for manufacturing the display device 100. For example, the controller COT may be implemented as a central processing unit (CPU) and/or other similar devices depending on hardware, software, and/or a combination thereof. Unless otherwise specified, operations performed during the manufacturing process of the display device 100 may be performed and/or controlled by the controller COT. In some embodiments, the controller COT may update the cavity effect information of the layer PTL to be formed based on the cavity effect information obtained by the inspector ISP in association with the previously formed layer(s) PFL. A target shape and/or a target thickness for forming the layer PTL may adjusted to compensate for process deviations associated with the formation of the previously formed layer(s) PFL.

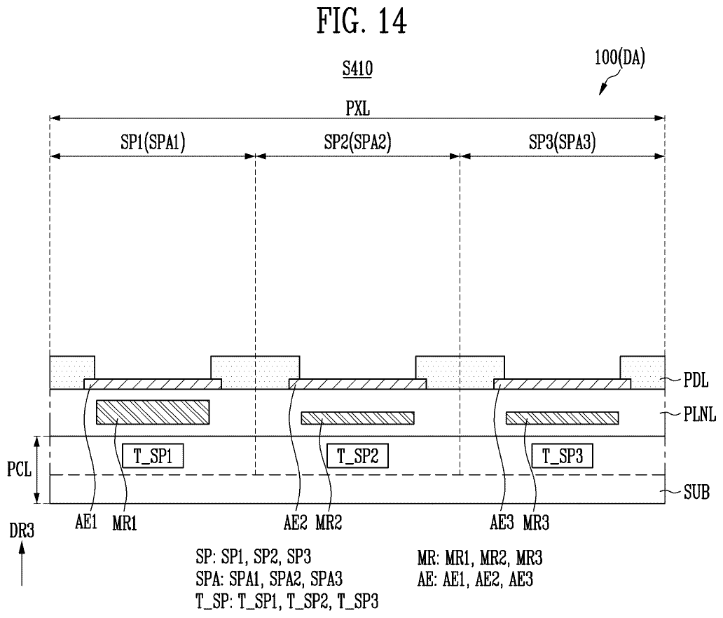

Referring to FIG. 6, FIG. 10, and FIG. 14, as part of forming the reflective layer MR and the anode electrode AE (S410), the reflective layers MR may be patterned on the pixel circuit layer PCL, and the planarization layer PLNL may be formed on the reflective layers MR. The anode electrodes AE may be patterned on the planarization layer PLNL, and the pixel defining layer PDL covering at least a portion of the anode electrodes AE and exposing portions of the anode electrodes AE may be patterned.

In some embodiments, the step S410 may be performed in an outer chamber formed outside a facility or a line in which the in-line type process ILN is performed. However, embodiments are not limited to the above-noted example.

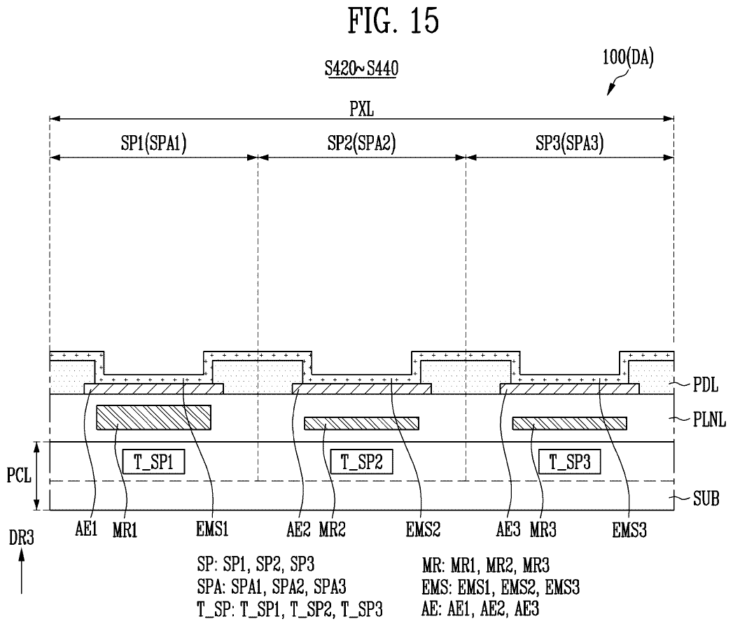

Referring to FIG. 6, FIG. 10, and FIG. 15, forming the hole transport portion HTU (S420), forming the light-emitting layer EML (S430), and forming the electron transport portion ETU (S440) may be sequentially performed to form the light-emitting structure EMS. At least a portion of the light-emitting structure EMS may be disposed in each of the sub-pixels SP.

In some embodiments, each of forming the hole transport portion HTU (S420), forming the light-emitting layer EML (S430), and forming the electron transport portion ETU (S440) may be a unit process step UST, and each of the unit process steps UST may include a corresponding first unit process step UST1 and a corresponding second unit process step UST2. However, embodiments are not limited to this example. For instance, in some embodiments, forming the cathode electrode CE (S480) may also be a unit process step UST.

In some embodiments, forming the hole transport portion HTU (S420) may include obtaining the first cavity effect information about previously formed layers PFL as part of the first unit process step UST1 (S422) and forming the hole transport portion HTU based on the first cavity effect information as part of the second unit process step UST2 (S424). Forming the light-emitting layer (S430) may include obtaining the second cavity effect information on previously formed layers PFL as part of the first unit process step UST1 (S432) and forming the light-emitting layer EML based on the second cavity effect information as part of the second unit process step UST2 (S434). Forming the electron transport portion ETU (S440) may include obtaining the third cavity effect information on previously formed layers PFL as part of the first unit process step UST1 (S442) and forming the electron transport portion ETU based on the third cavity effect information as part of the second unit process step UST2 (S444).

The light-emitting structure EMS including the hole transport portion HTU, the light-emitting layer EML, and the electron transport portion ETU, which may be sequentially formed in the recited order, may be formed. As described above, the cavity effect information about respective previously formed layers PFL may be used to update target formation specifications for forming layers PTL so that risks (or deviations from intended specifications), such as process errors in the formation of the cavity structure, may be compensated to improve the quality of the cavity formation.

In some embodiments, as part of respective first unit process steps UST1, the inspector ISP may perform an inspection process on one or more corresponding previously formed layers PFL, and based on the obtained cavity effect information, the controller COT may perform a compensation step for the cavity effect information to adjust target formation specifications for one or more corresponding layers PTL to be formed as part of respective second unit process steps UST2.

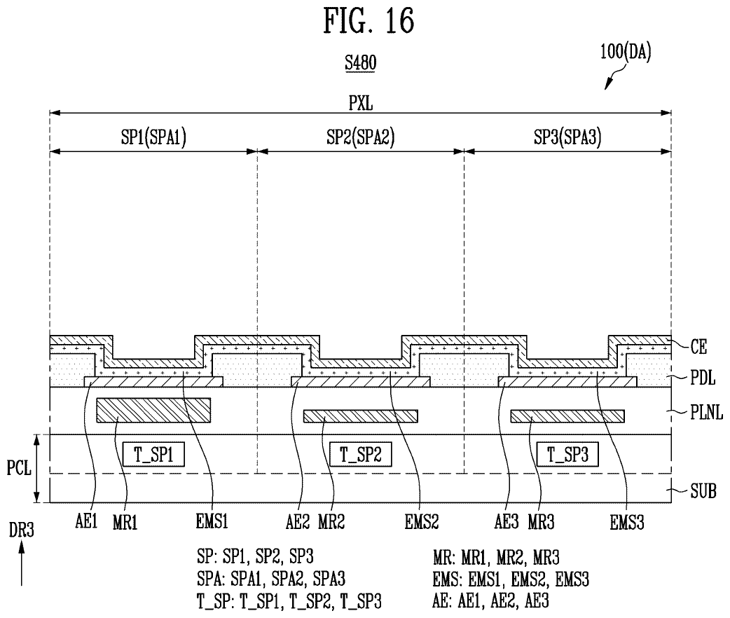

Referring to FIG. 6, FIG. 10, and FIG. 16, as part of forming the display layer DL (S400), forming the cathode electrode CE (S480) may be performed. For example, the cathode electrode CE may be formed on the light-emitting structure EMS in the sub-pixel areas SPA.

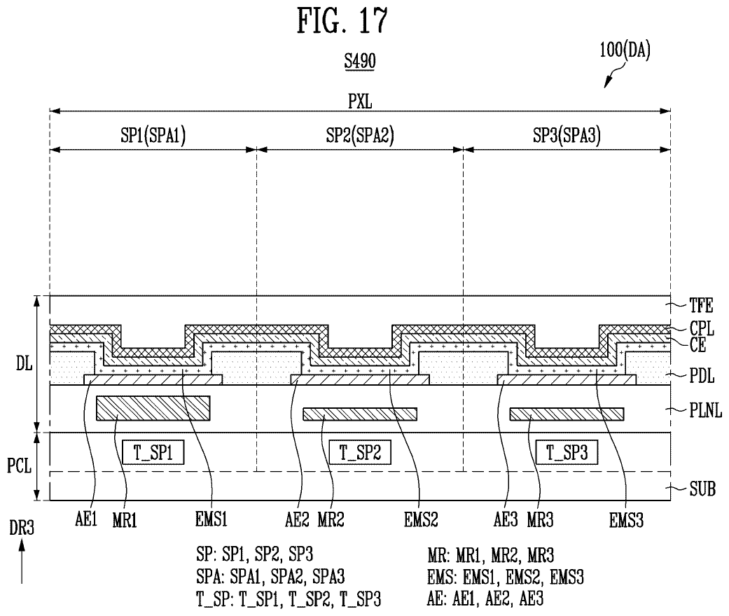

Referring to FIG. 6, FIG. 10, and FIG. 17, as part of forming the display layer DL (S400), forming the capping layer CPL and the encapsulation layer TFE (S490) may be performed. For example, the capping layer CPL and the encapsulation layer TFE may be formed on the cathode electrode CE in the sub-pixel areas SPA.

Referring to FIG. 6, as part of forming the upper layer (S600), multiple layers may be formed on the display layer DL. For example, the color filters CF may be patterned on the encapsulation layer TFE, the lenses LS may be patterned on the color filters CF, and the overcoat layer OC and the cover window CW may be disposed on the lenses LS.

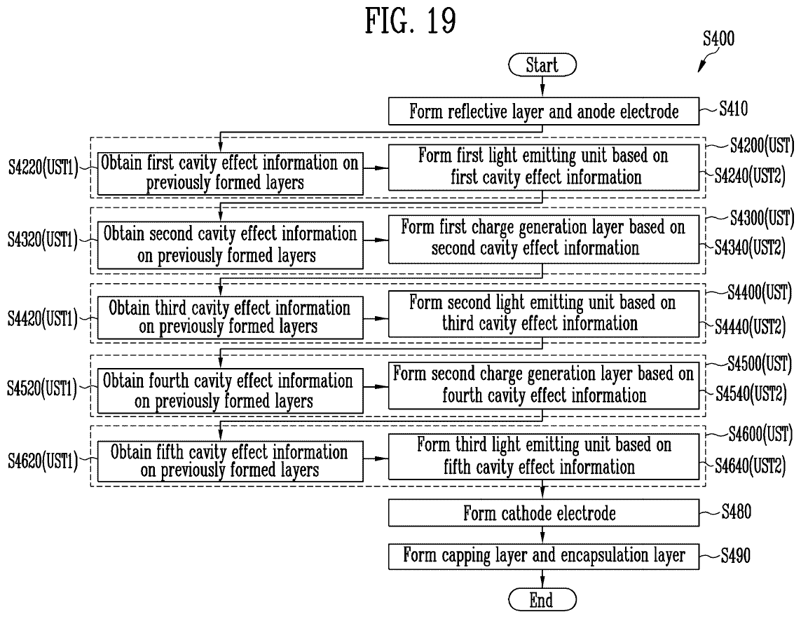

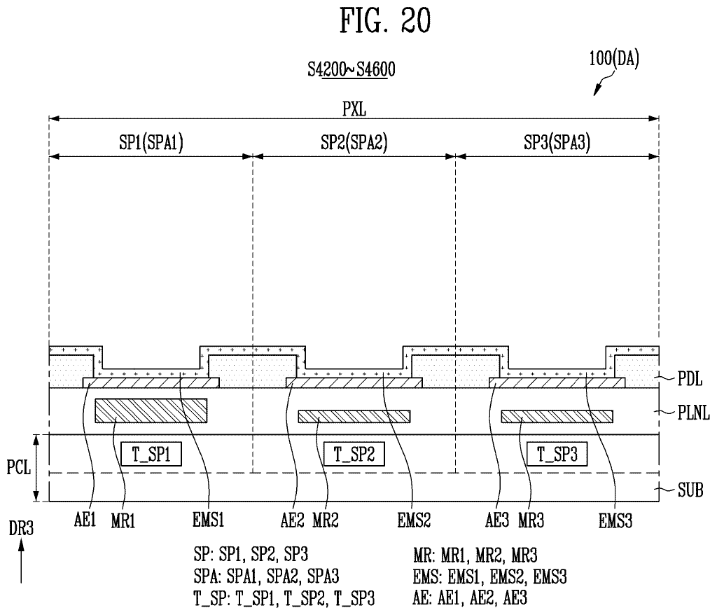

A method of manufacturing the display device 100 according to an embodiment will be described in connection with the unit process steps UST described above, but with reference to FIG. 19 and FIG. 20. Descriptions that may be redundant to those described above are simplified or are not repeated.

FIG. 19 and FIG. 20 illustrate schematic views of a method for manufacturing a display device according to an embodiment. FIG. 19 illustrates a flowchart of a method for forming a display layer according to an embodiment. FIG. 20 illustrates a schematic cross-sectional view of process steps of a method for manufacturing a display device according to an embodiment. For better understanding and ease of description, FIG. 20 illustrates a schematic cross-sectional structure based on the cross-sectional structure described above with reference to FIG. 3.

According to an embodiment, the light-emitting structure EMS may include a tandem structure, such as shown in FIG. 5. The previously formed layer(s) PFL may be a previously formed light-emitting unit EU, and the layer PTL to be formed may be another light-emitting unit EU to be formed on the previously formed light-emitting unit EU. Based on cavity effect information about the previously formed light-emitting unit EU, the cavity effect information or target formation specifications (e.g., thickness, cross-sectional structure, and/or the like) about the another light-emitting unit EU may be compensated or adjusted, and a more precisely designed or formed cavity structure may be provided.

Referring to FIG. 19 and FIG. 20, forming the display layer DL (S400) may include forming the reflective layer MR and the anode electrode AE (S410), forming the cathode electrode CE (S480), and forming the capping layer CPL and the encapsulation layer TFE (S490), similar to as described in association with FIG. 10 to FIG. 18, and the process of forming the display layer DL may include forming a first light-emitting unit EU1 (S4200), forming a first charge generation layer CGL1 (S4300), forming a second light-emitting unit EU2 (S4400), forming a second charge generation layer CGL2 (S4500), and forming a third light-emitting unit EU3 (S4600).

In some embodiments, each of forming the first light-emitting unit EU1, forming the first charge generation layer CGL1 (S4300), forming the second light-emitting unit EU2 (S4400), forming the second charge generation layer CGL2 (S4500), and forming the third light-emitting unit EU2 may be a unit process step UST, and each of the unit process steps UST may include a corresponding first unit process step UST1 and a corresponding second unit process step UST2.

In some embodiments, forming the first light-emitting unit EU1 (S4200) may include obtaining the first cavity effect information about the previously formed layers PFL as part of the first unit process step UST1 (S4220) and forming the first light-emitting unit EU1 based on the first cavity effect information as part of the second unit process step UST2 (S4240). Forming the first charge generation layer CGL1 (S4300) may include obtaining the second cavity effect information about the previously formed layers PFL as part of the first unit process step UST1 (S4320) and forming the first charge generation layer CGL1 based on the second cavity effect information as part of the second unit process step UST2 (S4340). Forming the second light-emitting unit EU2 (S4400) may include obtaining the third cavity effect information about the previously formed layers PFL as part of the first unit process step UST1 (S4420) and forming the second light-emitting unit EU2 based on the third cavity effect information as part of the second unit process step UST2 (S4440). Forming the second charge generation layer CGL2 (S4500) may include obtaining the fourth cavity effect information about the previously formed layers PFL as part of the first unit process step UST1 (S4520) and forming the second charge generation layer CGL2 based on the fourth cavity effect information as part of the second unit process step UST2 (S4540). Forming the third light-emitting unit EU3 (S4600) may include obtaining the fifth cavity effect information about the previously formed layers PFL as part of the first unit process step UST1 (S4620) and forming the third light-emitting unit EU3 based on the fifth cavity effect information as part of the second unit process step UST2 (S4640).

The light-emitting structure EMS including a tandem structure may be formed. As described above, the cavity effect information about respective previously formed layers PFL may be used to update target formation specifications for forming layers PTL so that risks (or deviations from intended specifications), such as process errors in the formation of the cavity structure, may be compensated to improve the quality of the cavity formation.

Hereinafter, an electronic device 1000 including the display device 100 in accordance with an embodiment will be described.

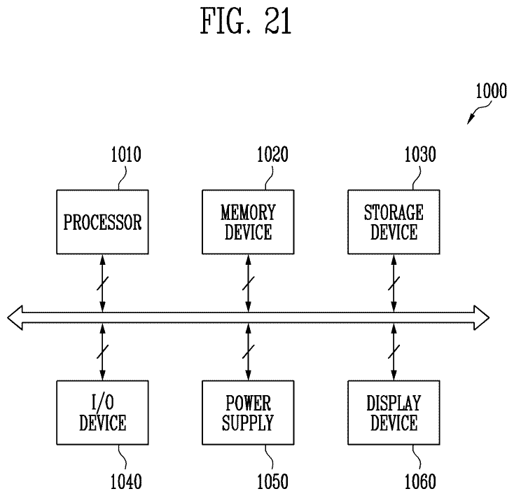

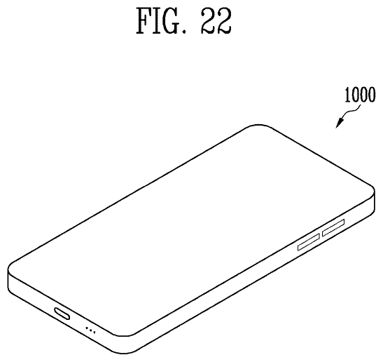

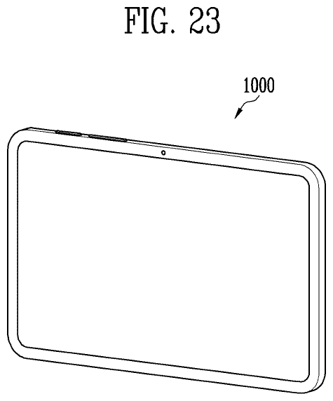

FIG. 21 is a schematic block diagram illustrating an electronic device 1000 including a display device in accordance with an embodiment. FIG. 22 is a schematic diagram illustrating an example where the electronic device 1000 of FIG. 21 is implemented as a smartphone. FIG. 23 is a schematic diagram illustrating an example where the electronic device 1000 of FIG. 21 is implemented as a tablet computer.

Referring to FIGS. 21 to 23, the electronic device 1000 may include a processor 1010, a memory device 1020, a storage device 1030, an input/output (I/O) device 1040, a power supply 1050, and a display device 1060. The display device 1060 may be the display device 100 of FIG. 1. The electronic device 1000 may further include various ports for communication with a video card, a sound card, a memory card, a USB device, or other systems. In an embodiment, as illustrated in FIG. 22, the electronic device 1000 may be a smartphone. In an embodiment, as illustrated in FIG. 23, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A method of manufacturing a display device, the method comprising:
forming a pixel circuit layer including a pixel circuit; and
forming a display layer including a light-emitting element disposed on the pixel circuit layer and electrically connected to the pixel circuit, wherein
forming the display layer includes unit process steps, and
each of the unit process steps includes:
obtaining, as part of a first unit process step, cavity effect information about one or more previously formed layers; and
forming, as part of a second unit process step, a layer based on the cavity effect information obtained as part of the first unit process step.

2. The method of claim 1, wherein
the layer is formed based on updated target information that is updated based on the cavity effect information obtained as part of the first unit process step.

3. The method of claim 1, wherein
the second unit process step compensates for a process deviation in at least one of the previously formed layers.

4. The method of claim 1, wherein
the cavity effect information includes thickness information about one or more of the previously formed layers.

5. The method of claim 4, wherein
in response to the previously formed layers being formed thicker or thinner than a target formation range, the layer is formed thinner or thicker than a target thickness range for the layer.

6. The method of claim 1, wherein
the cavity effect information includes surface uniformity information about one or more of the previously formed layers.

7. The method of claim 6, wherein
in response to at least one of the previously formed layers being formed with a non-uniform cross-section, the layer is formed to have a cross-section corresponding to the non-uniform cross-section.

8. The method of claim 1, wherein
forming the display layer includes forming an anode electrode, and
the anode electrode is at least one of the previously formed layers.

9. The method of claim 8, wherein forming the display layer includes, as steps respectively corresponding to the unit process steps:
forming a hole transport portion on the anode electrode;
forming a light-emitting layer on the hole transport portion; and
forming an electron transport portion on the light-emitting layer.

10. The method of claim 9, wherein
forming the hole transport portion includes:
obtaining, as part of another first unit process step, first cavity effect information about one or more of the previously formed layers; and
forming, as part of another second unit process step, the hole transport portion based on the first cavity effect information, and
the previously formed layers include the anode electrode.

11. The method of claim 10, wherein
forming the display layer includes forming a cathode electrode on the electron transport portion, and
a portion of the cathode electrode facing the light-emitting layer is formed to cavity-amplify incident light from the light-emitting layer.

12. The method of claim 11, wherein
forming the display layer includes forming a reflective layer on the pixel circuit layer, and
a portion of the reflective layer facing the light-emitting layer is formed to cavity-amplify incident light from the light-emitting layer.

13. The method of claim 1, wherein forming the display layer includes, as steps respectively corresponding to the unit process steps:
forming a first light-emitting unit;
forming a charge generation layer on the first light-emitting unit; and
forming a second light-emitting unit on the charge generation layer.

14. The method of claim 1, wherein
at least some of the unit process steps are performed as part of an in-line process in which processes of the in-line process are sequentially performed along a same manufacturing line.

15. The method of claim 1, wherein
the display device is an organic light-emitting diode (OLED) on silicon (OLEDoS) display device.

16. A display device manufactured according to the method of claim 1.

17. The method of claim 2, further comprising:
determining that the process deviation occurred in the at least one of the previously formed layers using the cavity effect information.

18. An electronic device comprising:
a processor configured to provide input image data;
the display device of claim 16, the display device being configured to display an image based on the input image data and including sub-pixel areas; and
a power supply configured to supply power to the display device.
